(19) United States
(12) Patent Application Publication
(10) Pub. No.: US 2019/0222162 A1
(43) Pub. Date: Jul. 18, 2019

(54) ELONGATE MEMBER MOUNTING SYSTEM FOR SECURING PHOTOVOLTAIC MODULE TO GROUND COVER SYSTEM

(71) Applicant: Watershed Solar LLC, Alpharetta, GA (US)

(72) Inventors: S. Kyle Ehman, Milton, GA (US); Michael R. Ayers, Johns Creek, GA (US)

(73) Assignee: Watershed Solar LLC, Alpharetta, GA (US)

(21) Appl. No.: 16/246,448

(22) Filed: Jan. 11, 2019

Related U.S. Application Data
(60) Provisional application No. 62/616,696, filed on Jan. 12, 2018.

(51) Int. Cl. H02S 20/10; H02S 30/10; H01L 31/05

(52) U.S. Cl. CPC H02S 20/10; H01L 31/05; H02S 30/10

(57) ABSTRACT

A mounting system for securing a photovoltaic module to a tufted geosynthetic cover to collect solar energy, with an attaching harness connected to a support of a photovoltaic module, the attaching harness extending laterally outwardly of the photovoltaic module, and an elongate member disposed between the tufted geosynthetic cover and a geomembrane overlying a ground surface. Fasteners extend through the attaching harness and into the elongate member, for securing the photovoltaic module to the tufted geosynthetic cover. A method of securing a photovoltaic module to a tufted geosynthetic cover is disclosed.

The present application claims benefit of U.S. Provisional Patent Application Ser. 62/616,696, filed Jan. 12, 2018.

### TECHNICAL FIELD

This invention relates to an integrated mounting system for photovoltaic modules for use in solar energy collection. In a more specific aspect, this invention relates to a non-ballasted and non-ground penetrating elongate member integrated photovoltaic mounting system for use with, and supported by, tufted geosynthetics.

In this application, the following terms will be understood to have the indicated definitions:
“photovoltaic module”—a module which utilizes the generation of voltage when radiant energy (such as solar energy) falls on the module; sometimes referred to as a solar cell or solar panel.
“tufted geosynthetics”—a system which is adapted to cover waste sites and other environmental closures and which is generally comprised of synthetic grass having synthetic fibers tufted to a backing and a geomembrane. Examples of a tufted geosynthetic cover system are shown in Ayers and Urrutia U.S. Pat. Nos. 7,682,105 and 9,163,375. The term “tufted geosynthetics” is also used to refer to a synthetic turf cover system.
“synthetic grass”—refers to a composite which comprises at least one geotextile (woven or nonwoven) tufted with one or more synthetic yarns or strands and which has the appearance of grass.
“geomembrane”—refers to a polymeric material, such as high density polyethylene, very low density polyethylene, linear low density polyethylene, polyvinyl chloride, etc.
“surface”—refers to a surface which has an angle of slope of zero or more.
“creep”—refers to a behavior of materials (such as soils and geosynthetics) to move or deform slowly under a constant load or stress.

### BACKGROUND OF THE INVENTION

Photovoltaic solar modules have historically been mounted by use of a rigid racking system over a variety of surfaces such as rooftops, greenfields and brownfields. These rigid racking systems have not been integrated onto the photovoltaic module. Typical systems include racking structures that the photovoltaic module must be placed upon and then mechanically fastened to the racking structure.

Racking structures are placed in spaced-relation and the racking structures enable orienting the photovoltaic module at an energy-generating efficient angle. However, the spacing limits the number of photovoltaic modules that can be installed in an area because the angling causes shadows. An adjacent rack must be spaced sufficiently that the photovoltaic modules are not within a shadow area.

There is a need in the solar industry for an integrated photovoltaic module in which the mounting mechanism is attached to the photovoltaic module which eliminates the need for a rigid racking system. The integration allows for an economical alternative to a traditional rigid racking system and enables the increasing of the density of the photovoltaic modules placed at a solar energy generation site, thereby increasing the potential generation of electrical power while allowing flexibility of installation by using non-traditional racking installers.

While use of solar as a renewable alternative energy source has “clean energy” favorabilities, there are drawback to such installations. Solar energy generation sites typically require large tracts of land. In some location circumstances, wooded lands are cleared or farm lands are re-purposed for use as solar energy generation sites. Other sites are significantly remote from tie-in connections to the power transmission and distribution grid of power generating and supply companies. These remote sites require capital expenditures to install and maintain transmission lines to the electrical grid and such transmission lines occupy additional land. Also, recent changes in power generation capacity has decreased reliance on coal and increased reliance on cleaner combustion fuels such as natural gas and, alternatively, power plants that generate electricity with turbines operated with steam heated by nuclear fuel sources. The coal-fired power plants nevertheless have large areas of ash holding ponds or storage areas. These areas are subject to closing with covers such as geomembranes that restrict environmental waters, such as rain or other precipitation or surface water flow, from passing through the covered site and leaching into the ground or pond.

Accordingly, there is a need in the art for an improved integrated mounting system for securing photovoltaic modules to a surface for generating solar power. It is to such that the present invention is directed.

### SUMMARY OF THE INVENTION

The present invention meets the need in the art by providing an apparatus for securing a photovoltaic module to a tufted geosynthetic cover overlying a ground surface, with a pair of attaching harnesses each for extending laterally from a pair of supports spaced apart on a respective opposing sides of a photovoltaic module, and a pair of elongate members for disposing between a tufted geosynthetic cover and a geomembrane overlying a ground surface, each of said elongate members on a respective opposing side of the photovoltaic module. A plurality of fasteners each for extending through a respective one of the attaching harnesses and into a respective elongate member, for securing the photovoltaic module to the tufted geosynthetic cover.

In another aspect, the present invention provides a method of securing a photovoltaic module to a tufted geosynthetic cover, comprising the steps of:

(a) connecting an attaching harness to a support of a photovoltaic module;

(b) extending the attaching strip laterally of a side of the photovoltaic module;

(c) inserting an elongate member between a tufted geosynthetic cover and a geomembrane overlying a ground surface along a side of the photovoltaic module; and

(d) driving a fastener through the attaching harnesses and into the elongate member, for securing the photovoltaic module to the tufted geosynthetic cover.

In yet another aspect, the present invention provides an apparatus for securing a photovoltaic module to a tufted geosynthetic cover overlying a ground surface, comprising an attaching harness for extending laterally from the support outwardly of a side of the photovoltaic module, and an elongate member for disposing between a tufted geosynthetic cover and a geomembrane overlying a ground surface. A plurality of fasteners each for extending through the attaching harness and into the elongate member, for securing the photovoltaic module to the tufted geosynthetic cover.

The integrated mounting system of this invention allows for easy installation of a photovoltaic module supported by a tufted geosynthetic on a surface. This combination of the integrated mounting system and tufted geosynthetic results in a lower cost, lower maintenance of the surrounding surface, adaptable for variety of grades from flat to sloping ground and generates more solar power per unit area.

Briefly described, the present invention integrates a photovoltaic module mounting system over tufted geosynthetics on various surfaces (such as a ground cover system, roof, reservoir, pond, etc.). There are two components of this invention that may be used within the integrated photovoltaic module mounting system, in which the integrated mounting system has a flexible attachment connection and an elongate support member. The attachment connection in accordance with the present invention attaches at a first portion to a bottom, top or side of the photovoltaic module and a lateral second portion that overlies and mechanically connects (e.g., screws, bolts, etc.) to the support member disposed below a tufted geosynthetic ground cover. Other means of attaching the attachment connection to the tufted geosynthetic include adhesive means such as glue, tape, etc.

These two components eliminate the need for ballast compared to a traditional photovoltaic racking system which does not have foundation anchoring. The integrated photovoltaic module mounting system supported by a tufted geosynthetic requires no ballast on a surface.

Alternatively, optionally the photovoltaic module mounting system further includes one or more anti-creep strip(s) that enhances interface friction between the photovoltaic module and the tufted geosynthetic, while also reducing shearing forces between the photovoltaic module and its mounting surface, thus preventing or substantially preventing sliding forces from mobilizing the module. If desired, a monitoring device can be used to measure the amount of creep. The mounting system is used alone, or alternatively with the anti-creep strip(s) as an additional factor to increase interface friction and to counter potential shearing and uplift forces which could be caused by high wind gusts.

The result of a non-ballasted integrated photovoltaic module mounting system allows for a lower cost and increased power generation through higher density of module placement at an energy generation site An additional advantage of an integrated photovoltaic module mounting system is that the system does not require grounding. The integrated photovoltaic module mounting system of this invention allows for a higher density (i.e., one or more) of photovoltaic modules in a defined area as compared to traditional systems, and a higher density of modules enables the integrated photovoltaic module mounting system to provide more electrical power per unit area.

Objects, advantages, and features of the present invention will become apparent upon a reading of the detailed description in conjunction with the drawings.

### BRIEF DESCRIPTION OF THE DRAWINGS

FIG. 1 shows multiple flexible attachment connections (i.e., several single attachment harnesses) mounted on a photovoltaic module.

FIG. 1A shows a detailed bottom view of a single flexible attachment connection exploded away from a mounting baseplate attached to photovoltaic solar module.

FIG. 2 is a view of multiple elongated harness strips mounted on opposing sides of a photovoltaic module.

FIG. 3 is a view of two anti-creep strips mounted on a photovoltaic module.

FIG. 4 is a view of multiple single attachment harnesses used with multiple anti-creep strips.

FIG. 5A is a view of two elongated attachment harness strips used with multiple anti-creep strips.

FIG. 5B shows two elongated attachment harness strips used with a single anti-creep strip.

FIG. 5C shows two elongated attachment harness strips used with multiple anti-creep strips and multiple single weld harnesses.

FIG. 6 shows a cross section of a single attachment harness strip used with a photovoltaic module.

FIG. 6A illustrates in side elevational view an embodiment of the photovoltaic module mounting system using a tilting device for selective orienting at an angle to the geosynthetic for optimal positioning relative to the sun for energy generation.

FIG. 7 shows a top view of a single attachment harness.

FIG. 8 illustrates in top plan view an embodiment of an integrated mounting system for securing a photovoltaic module to a tufted geosynthetic ground cover.

FIG. 9 illustrates in cross-sectional end elevational view the integrated mounting system illustrated in FIG. 8.

FIG. 10 illustrates a detailed bottom view of a photovoltaic solar module having a mounting baseplate attached with adhesive to the bottom surface, with a single flexible attachment connection positioned intermediate the baseplate and an anti-creep strip for use with the integrated mounting system.

FIG. 11 illustrates a fastener with a stress distribution plate received through the anti-creep strip and flexible attachment connection to engage the mounting baseplate attached to the solar module with a portion of the flexible attachment connection extending laterally as a flap for overlying and mechanically connecting to a support member disposed below a tufted geosynthetic ground cover.

### DETAILED DESCRIPTION

The present invention provides an integrated photovoltaic module mounting system for use with a tufted geosynthetic system on a surface without a racking structure and without ballast for support.

The essential components of this invention are a tufted geosynthetic system, a photovoltaic module, and one or more integrated photovoltaic module mounting systems.

Cover System Examples of tufted geosynthetic systems useful in the integrated photovoltaic module mounting system of this invention are the covers marketed by Watershed Geosynthetics LLC under the registered trademarks ClosureTurf and VersaCap. These covers comprise a composite of at least one geotextile which is tufted with one or more synthetic yarns (i.e., a tufted geosynthetic) and an impermeable geomembrane comprised of a polymeric material.

The synthetic grass of the system may contain an infill material and/or a material for protection of the synthetic grass against ultraviolet rays.

Solar Module

One or more multi-crystalline solar modules can be used in the integrated photovoltaic module mounting system of this invention, such as commercially available polycrystalline silicon solar modules. Examples of effective solar modules are available from BYD (China) under the designation BYD 260P6C-30-DG and from Trina (China) under the designation Solar Duomax TSM-PEG14. Other solar panels may be gainfully used.

Wind Uplift Resistance

The present invention comprises a wind-resistant non-ballasted integrated photovoltaic module mounting system for use on a tufted geosynthetic that preferably includes both an attachment layer (referenced herein as “attaching harness”) and an elongate member disposed between a tufted geosynthetics and a geomembrane, with fasteners securing the attachment layer to the elongate member, and optionally anti-creep strips connected to a support of the photovoltaic module. The system does not rely on weight to resist wind forces, but instead relies on wind-breaking turf blades (i.e., the synthetic grass) and an attachment to the elongate member covered by the turf blades (synthetic grass). The ground cover can be deployed over a large area with very minor ballasting. Wind-breaking elements may also be utilized to break up the airflow over the integrated photovoltaic module to provide wind uplift resistance.

With this invention, the wind velocity becomes turbulent near the surface of the tufted geosynthetic cover, thus greatly reducing the actual wind velocity at the liner surface and decreasing associated uplift. The reaction of the synthetic grass of the tufted geosynthetic to the wind forces can also create a downward force on the tufted geosynthetic cover and the underlying geomembrane. This reaction is caused by the filaments of the synthetic grass applying an opposing force against the wind which is transferred as a downward force on the geomembrane.

The integrated photovoltaic module of this invention can be used with an optional tilting device to raise or lower the module for better energy generation results depending on the location.

Friction

This invention also optionally provides structure and method for a non-ballasted module system utilizing one or more anti-creep strips integrated on the module when mounted over tufted geosynthetics, by increasing the coefficient of friction between the anti-creep strips and the tufted geosynthetic.

The anti-creep strips footing is generally a structured geomembrane.

The anti-creep strips, when used in this invention, comprise a polymeric material such as polyethylene, polypropylene, ethylene propylene diene monomer, rubber, metal, textured metal, polyvinyl chloride, polyurethane, etc. having a field or array of projections, nubs, feet, studs or the like.

When used in this invention, suitable materials for infill are sand, concrete and materials available from Watershed Geosynthetics LLC (Alpharetta, Ga.) under the trademarks HydroBinder and ArmorFill. Infill can be of various colors, sizes and textures.

When used in this invention, examples of suitable materials for anti-creep strips are calendared, textured and structural membranes made by Agru America, Inc. under the trademark SureGripnet.

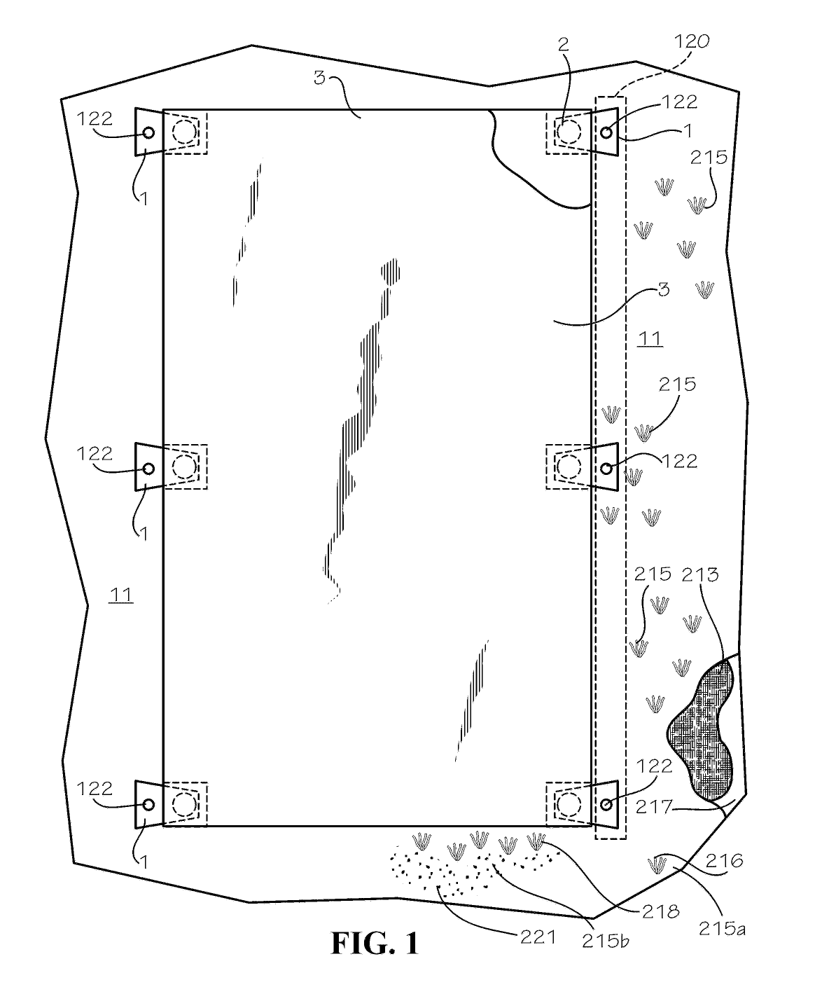

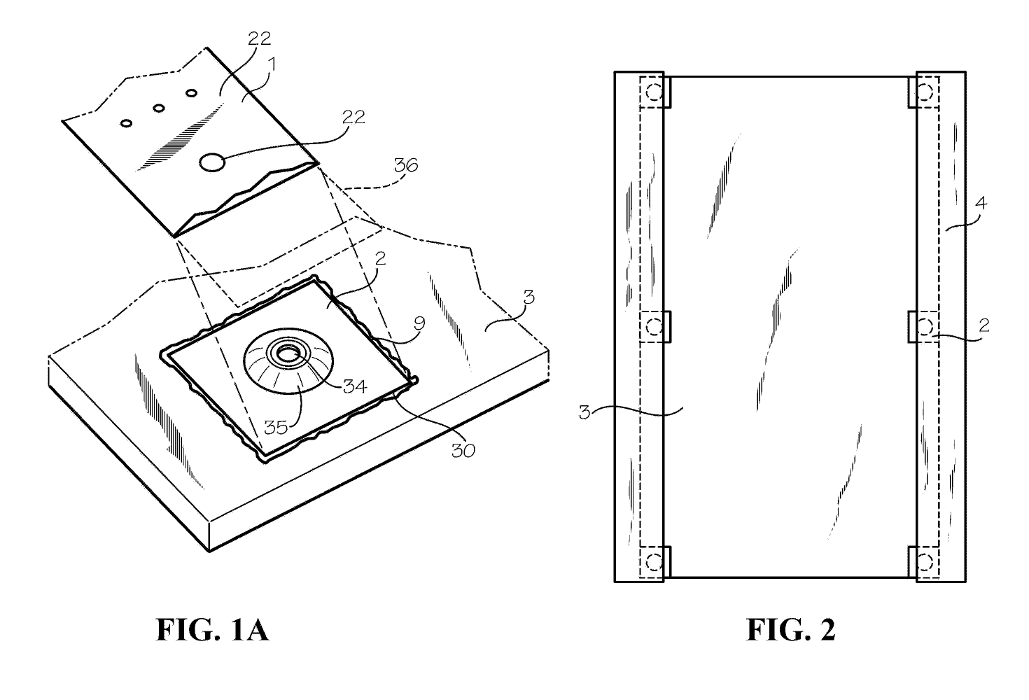

Referring now to the drawings, in which like numerals represent like elements, FIG. 1 shows multiple single attachment harnesses 1 (flexible attachment connections) secured by a mounting baseplate 2 that attaches to a solar module 3. The attachment harness 1 extends laterally over a tufted geosynthetic cover 11 for securing to an elongate member 120 with fasteners 122 as discussed below.

FIG. 1A shows a detailed bottom view in which a single flexible attachment connection 1 is exploded away from the mounting baseplate 2 that attaches with adhesive 30 to a bottom surface of the photovoltaic solar module 3. The flexible attachment connection 1 has a first portion that defines an opening 32 for receiving a fastener such as a screw or bolt that engages a threaded passage 34 in the baseplate 2. The threaded passage 34 extends in a raised spacer portion 35 of the baseplate 2, such as a nut mounted therein. A second portion 36 of the flexible attachment connection 1 extends laterally as a flap to overlie and mechanically connect (e.g., screws, bolts, etc.) to a support member (discussed below) disposed below a tufted geosynthetic ground cover.

FIG. 2 shows multiple elongate attachment harness strips 4 secured by mounting baseplates 2 attached to the solar module 3.

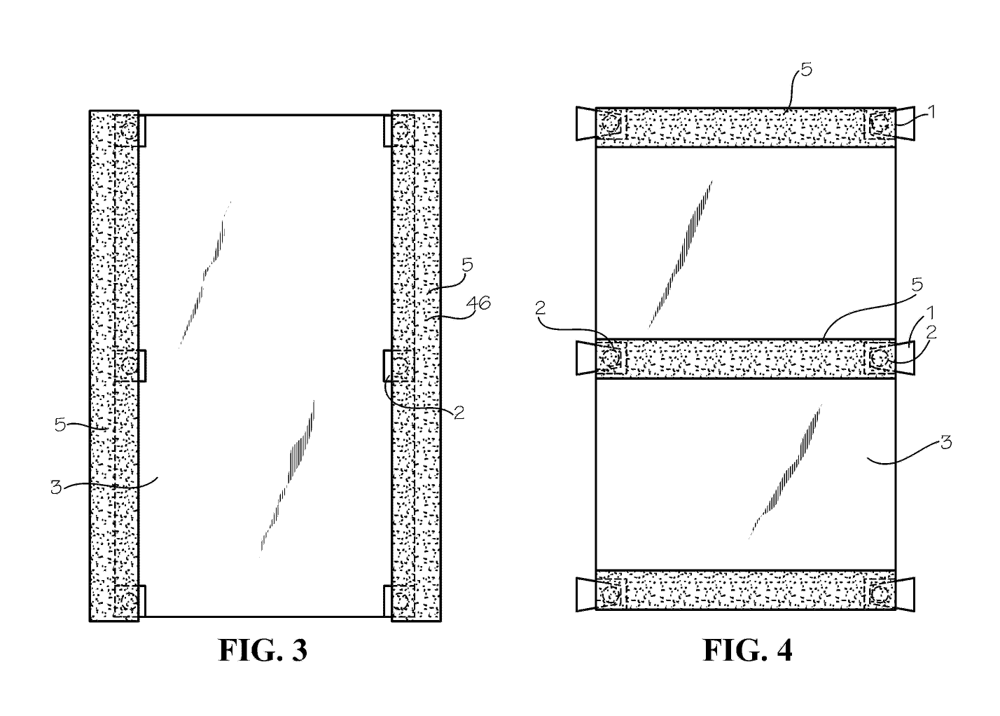

FIG. 3 shows two anti-creep strips 5 secured by mounting baseplate 2 attached to solar module 3.

FIG. 4 shows multiple single attachment harnesses 1 in combination with anti-creep strips 5, both secured by respective mounting baseplates 2 attached to the solar module 3.

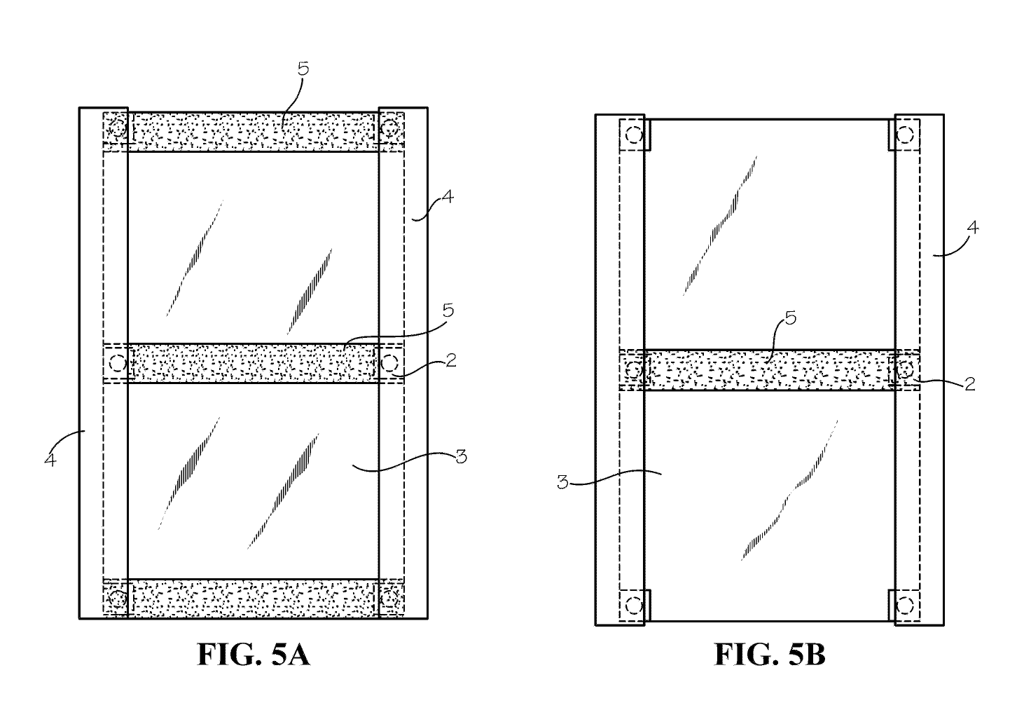

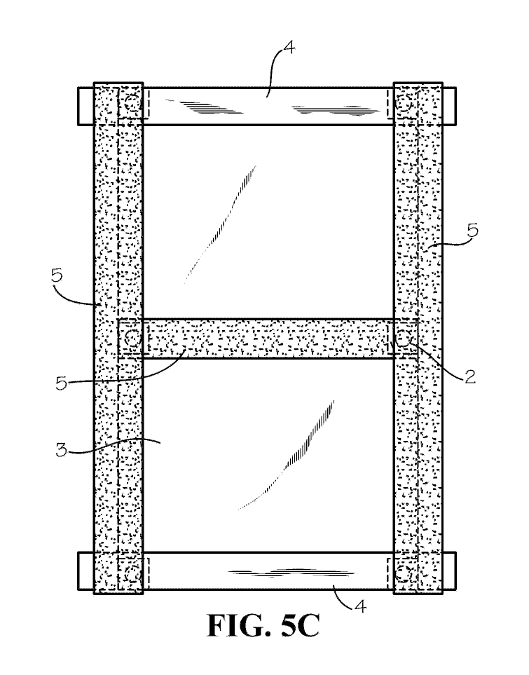

FIG. 5A shows two attachment harness strips 4 in combination with anti-creep strips 5 secured by mounting baseplate 2 attached to solar module 3.

FIG. 5B shows two attachment harness strips 4 used with a single anti-creep strip 5 secured by the mounting baseplate 2 attached to solar module 3.

FIG. 5C shows two attachment harness strips 4 used with multiple anti-creep strips 5 and secured by mounting baseplate 2 attached to solar module 3.

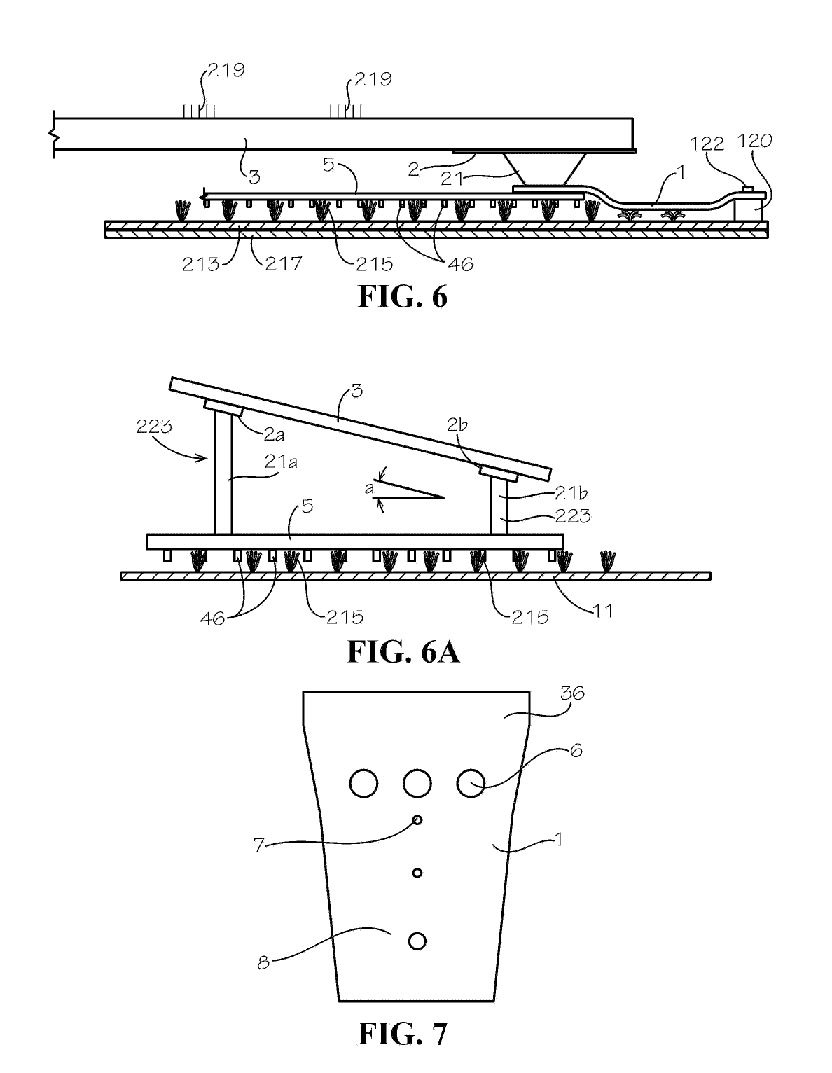

FIG. 6 shows a cross section of a single weld attachment harness 1 secured to the support 21 for the solar module 3.

FIG. 6A illustrates in side elevational view an embodiment of the photovoltaic module mounting apparatus using a tilting device generally 223 for selective orienting of the photovoltaic module 3 at an angle a to the geosynthetic cover 11 for optimal positioning relative to the sun for energy generation and/or for directed flow of precipitation water off of the photovoltaic module. The present invention comprises a wind-resistant non-ballasted integrated photovoltaic module mounting system for use on the tufted geosynthetic 11, which may include optionally anti-creep strips. The system does not rely on weight to resist wind forces, but instead relies on wind-breaking turf blades (i.e., the synthetic grass) and an attachment to the tufted geosynthetic 11. The tufted geosynthetic 11 cover can be deployed over a large area with very minor ballasting.

Optionally, wind-breaking elements 219 may also be utilized to break up the airflow over the integrated photovoltaic module to provide further wind uplift resistance. As illustrated in FIG. 6, one or more wind breaking elements generally 219 may attach to an edge of the photovoltaic module 3. The wind breaking elements 219 comprise a plurality of thin spaced-apart pins that extend upwardly, for example, about 1-12 inches, preferably about 2-6 inches, and more preferably, about 2-3 inches. In an alternate embodiment shown in FIG. 7, the weld harness 1 may include wind breaking or disturbing openings 6.

With this invention, the wind velocity on the impermeable surface (geo-membrane) becomes turbulent near the surface of the cover, thus greatly reducing the actual wind velocity at the liner surface and decreasing associated uplift. The reaction of the synthetic grass of the tufted geosynthetic to the wind forces can also create a downward force on the geomembrane. This reaction is caused by the filaments of the synthetic grass applying an opposing force against the wind which is transferred as a downward force on the geomembrane.

The integrated photovoltaic module of this invention can be used with an optional tilting device to raise or lower the photovoltaic module for better results depending on the location. FIG. 6A illustrates in side elevational view an embodiment of the photovoltaic module mounting apparatus using the tilting device generally 223 for selective orienting of the photovoltaic module 3 at an oblique angle a relative to the geosynthetic cover 11 for optimal positioning relative to the sun for energy generation. The tilting device 223 comprises at least a pair of the mounting base plates 2a, 2b having riser portions 21a, 21b of different lengths, whereby the photovoltaic module 3 is disposed at the angle a to the geosynthetic cover 11, for optimal energy generation and also for precipitation water flow off of the photovoltaic module.

Further, the mounting baseplate 2 spaces the solar photovoltaic module 3 from the tufted geosynthetic ground cover 11. The spacing thereby creates a gap between the tufted geosynthetic ground cover and the solar photovoltaic module 3, which gap facilitates air flow therealong for heat dissipation in that heating of the solar photovoltaic module 3 which occurs reduces the solar generation efficiency of the photovoltaic module. In an alternate embodiment, the mounting base plate 2 is sized to provide at least an 18 inch to 24 inch gap under the photovoltaic module 3.

To further enhance solar generation energy capacity, the photovoltaic module 3 is bifacial and the tufted geosynthetic ground cover 11 includes light reflective features, such as reflectants added into the polymeric used the extrusion of the yarn from which the tufts 215 are formed during tufting. As shown in FIG. 1, tuft 215a illustrates a reflectant 216, for example, a small light-reflecting body or chip. Further, a light reflective color pigment material may be included in the polymeric to enhance reflectivity of ambient light from the tufted geosynthetic ground cover 11 proximate the photovoltaic solar module 3. For example, tufts 215b are tufted with yarns that include a coloring pigment 218.

FIG. 7 shows a top view of a single attachment harness 1 having a single attachment 8 in combination with wind disturbing openings 6 and openings 7 for attaching optional mechanical connections. The elongated strips 4 include spaced-apart sets of openings 6, 7, and 8 for connection at respective mounting baseplates.

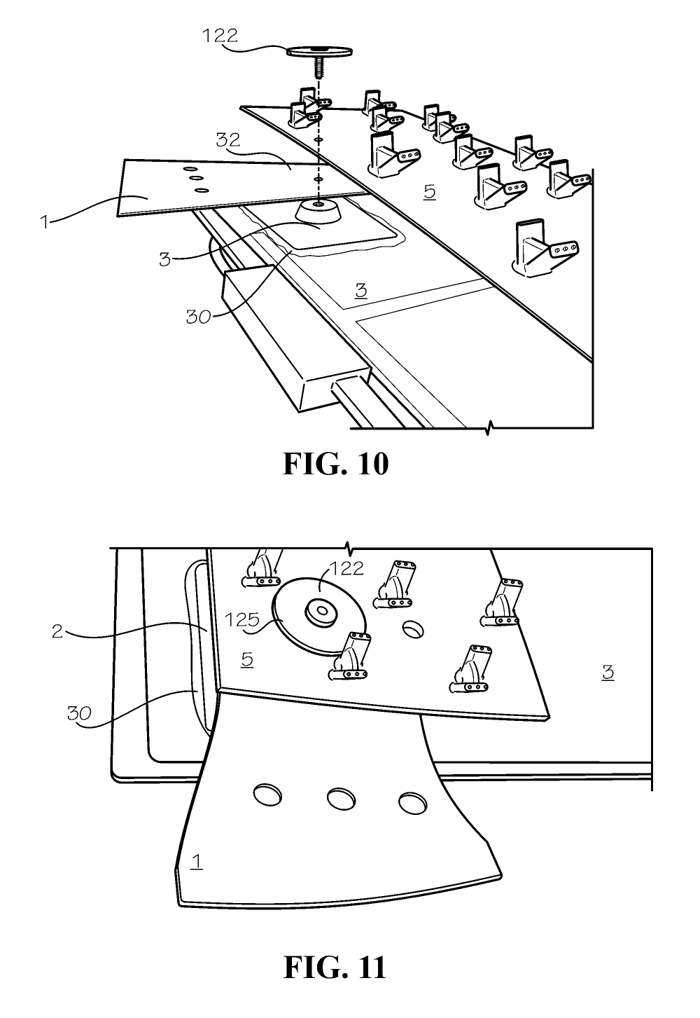

FIG. 10 illustrates a detailed bottom view of the photovoltaic solar module 3 having a mounting baseplate 2 attached with adhesive 30 to the bottom surface, with a single flexible attachment connection (attachment harness) 1 for use with the integrated mounting system positioned intermediate the baseplate and the optional anti-creep strip 5. A fastener passes through the anti-creep strip and the opening in the flexible attachment connection for threadably engaging the threaded passage 34 in the baseplate 2. As shown in FIG. 11, the fastener 122 may include a stress distribution plate 124, or washer. The stress distribution plate 124 seats on the surface of the anti-creep strip 5 secured by the fastener 122 that connects through the anti-creep strip and the flexible attachment connection to the mounting baseplate 2. The second portion 36 of the flexible attachment connection 1 extends laterally as a flap for overlying and mechanically connecting (e.g., screws, bolts, etc.) to the support member 120 disposed below the tufted geosynthetic ground cover.

An alternate embodiment uses the elongated flexible attachment connection or harness strips 4, that extend longitudinally for a distance substantially the length of the solar module 3 or a length of a plurality of the spaced-apart solar modules. Also, the anti-creep strip 5 may be longer to connect to multiple solar panels disposed in spaced-apart relation. Thus, the anti-creep strip 5 may have a length for extending across two or more of the solar modules 3. Such elongated harness strips 4 and/or anti-creep strip 5 thereby further interlock the plurality of solar modules 3 together, which solar modules are disposed in spaced-apart relation as an array of rows of solar modules on a tufted geosynthetic ground cover.

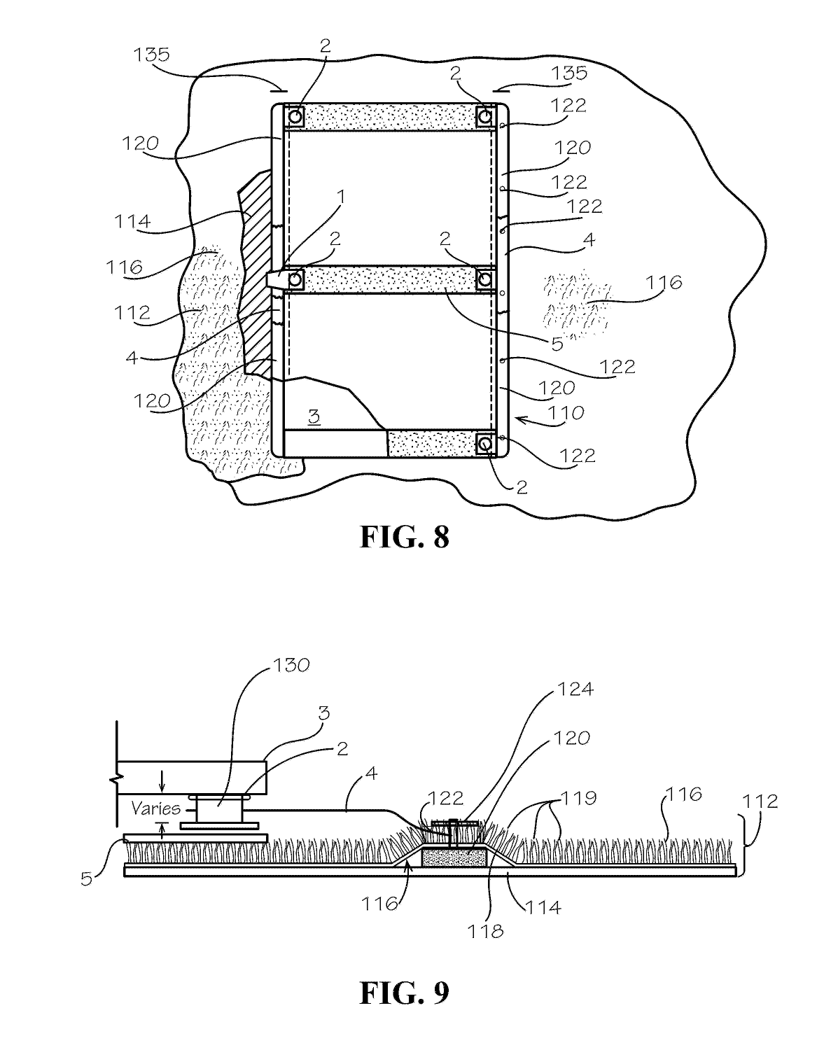

With reference next to FIG. 8 that illustrates in top plan view an integrated mounting system 110 according to the present invention for attaching the photovoltaic solar module 3 over a tufted geosynthetics ground cover system generally 112. With reference also to FIG. 9, the geosynthetics ground cover system 112 includes a geomembrane 114 that covers a large surface area and a tufted geosynthetic cover 116 that overlies the overlies the geomembrane 114. The geosynthetic cover 116 comprises a geosynthetic fabric 118 tufted with yarn tufts 119. As used herein, “tufted geosynthetics” refers to a cover system which is generally comprised of synthetic grass having synthetic fibers tufted to a backing and a geomembrane and which is adapted to cover waste sites and other environmental closures. Examples of a tufted geosynthetic cover systems are shown in Ayers and Urrutia U.S. Pat. Nos. 7,682,105 and 9,163,375. Examples of landfill covers useful in the solar energy system of this invention are the covers marketed by Watershed Geosynthetics LLC under the registered trademarks ClosureTurf and VersaCap. These covers comprise a composite of at least one geotextile which is tufted with one or more synthetic yarns (i.e., a tufted geosynthetic) and an impermeable geomembrane which is comprised of a polymeric material.

The mounting system 110 comprises a pair of elongated members 120 each positioned between the geomembrane 114 and the geosynthetic cover 116 on respective opposing sides of the photovoltaic solar module 3. The elongated member 120 has a length that is substantially the length of the side of the photovoltaic solar module 3. In an alternate embodiment, the elongated member 120 has a length extending for multiple solar module panels. The opposing distal ends of the elongated member 120 preferably define a bull nose, or curved face, for a purpose discussed below. A plurality of fasteners 122 secure the geosynthetic cover 116 to the elongated member. In the illustrated embodiment, the fasteners 122 are threaded screws. Alternate fasteners (bolts, rivets) may be used. The fastener 122 passes through the geosynthetic cover 116 and a side portion of the weld harness 39, and engages the elongated member 120. The fastener 122 preferably includes a stress distribution plate 124, such as a large washer, that distributes stress at the point of engagement of the fastener 122 with the geosynthetic cover 116 and the attachment harness 4. The fasteners 122 are positioned in spaced-apart relation along the length of the elongated member 120. The fasteners 122 and plates 124 may include a sealant to prevent water infiltration.

The mounting bracket 2 attached to the bottom surface of the photovoltaic solar module 3 engages the attachment harness 1. In the illustrated embodiment, the mounting bracket 2 includes a spacer 130. The spacer 130 is of a selected length. In an alternate embodiment, the spacers at a first end of the photovoltaic solar module 3 are longer than the spacers at the opposing end, whereby the photovoltaic solar module 3 may be oriented at a slight angle relative to the geosynthetics ground cover system 112, for example, for angling the solar module somewhat favorably towards the sun, without creating a shadow that overlies an adjacent solar module and further, for providing a slope for water drainage off of the photovoltaic module.

With continuing reference to FIGS. 8 and 9, the mounting system 110 attaches the photovoltaic solar module 3 to the tufted geosynthetics ground cover system 112. The attachment harness 1 attaches as discussed above to the photovoltaic solar module 3. The attachment harness 1 extends laterally as a flap across the tufts 119 of the geosynthetic cover 116. A slit 135 is cut through the geosynthetic cover 116 proximate a respective first end of the photovoltaic solar module 3 aligned with the positioning of the flap 36 of the attachment harness 1. An end of the elongate member 120 inserts through the slit 135 and the elongate member is moved longitudinally parallel to the side of the solar module 3 (or to the location on the geosynthetic cover for the positioning of the photovoltaic module. The bull nose curved face of the elongated member 120 facilitates passage of the elongated member in a space between the geomembrane 114 and the tufted geosynthetic cover 116. A rubber hammer may be used gainfully to tap on the opposing end of the elongated member 120 during installation movement.

The elongate member 120 is thereby disposed in position relative to the photovolatic panel 3 between the geomembrane 114 and the tufted geosynthetic cover 116. The slit 135 is closed for sealing from water infiltration. The slit 135 may be closed by heat sealing a tufted patch overlying the slit, by a polymeric binder material, or an adhesive. The fasteners 122 each receive one of the stress distribution plates 124. The fasteners 122, driven by a power screw driver through the weld harness 39 and the geosynthetic cover 116, and threadingly engage the elongated member 120. A plurality of fasteners 122 secure the flap of the weld harness 39 to the elongated member, to secure the photovoltaic solar module 3 to the tufted geosynthetics ground cover system 112. The elongated members 120 secure the solar module 3 from movement such as by wind forces over the tufted ground cover system 112 while the solar module 3 generates electrical energy upon exposure to the sun. The fasteners 122 may be sealed, for example, by a gasket or rubber or polymeric material.

A slit similar is formed on the opposing side of the photovoltaic module 3, and receives one of the elongate members 120 as discussed above. The slit is closed, and the opposing side of the photovoltaic module secured with the fasteners 122 to the tufted geosunthetic cover and the elongate member thereunder.

In an alternate embodiment, a pair of aligned slits 135 are made in the tufted geosynthetic cover 116 in spaced-apart relation proximate the solar panel 3. An elongated rod, such as a metal or fiberglass rod, inserts through a first one of the slits 135 between the geomembrane 114 and the tufted geosynthetic cover 116. The rod is pushed longitudinally for exiting of the leading end through the opposing slit. A cord attaches to a distal end of the rod proximate the first slit 135. A free end of the cord attaches to the elongated member 120. The rod is pulled from the passageway formed by the slits in the tufted geosynthetic cover 116. The cord, exiting from the slit, is pulled to move the elongated member 120, and guided by installation personnel at the opposing end, moves into the space between the geomembrane 114 and the tufted geosynthetic cover 116. The slits 135 are closed as described above. The photovoltaic module 3 attaches to the elongated member 120 with the fasteners 122 as discussed above.

Optionally used, the anti-creep strip 44 further prevents relative movement of the photovoltaic module 3 with respect to the tufted geosynthetic.

It should be understood that in these embodiments the attachment harness strip is preferably made of a polyethylene material. Similarly, the yarns of the tufted geosynthetic material are also made of a polyethylene material. With this construction, the melting point of the attachment harness strip is generally that of the yarns of the tufted geosynthetic material, thereby creating a superior hold or weld therebetween. However, it should be understood that other types of polymer materials may also be used for these components without departing from the scope of the invention.

The distinct advantage to the invention described in the embodiments herein is that the solar panels may be positioned or arranged in a manner that provides for a higher density of solar panels per area of land (for example, a series of rows of spaced-apart end-to-end solar modules 3). This higher density allows for the generation of more electricity per land area. Another advantage is the easy of mounting solar panels without the need for a racking system or without the occurrence of panel movement over time.

This invention has been described with particular reference to certain embodiments, but variations and modifications can be made without departing from the spirit and scope of the invention.

What is claimed is:

1. An apparatus for securing a photovoltaic module to a tufted geosynthetic cover overlying a ground surface, comprising:
a pair of attaching harnesses each for extending laterally from the support on a respective opposing side of the photovoltaic module;
a pair of elongate members for disposing between a tufted geosynthetic cover and a geomembrane overlying a ground surface, each of said elongate members on a respective opposing side of the photovoltaic module; and
a plurality of fasteners each for extending through a respective one of the attaching harnesses and into a respective elongate member, for securing the photovoltaic module to the tufted geosynthetic cover.

2. The apparatus as recited in claim 1, wherein the elongate member has a curved face at a distal end.

3. The apparatus as recited in claim 1, wherein the elongate member has a bull face at a distal end.

4. The apparatus as recited in claim 1, further comprising a pair of spacers for seating in spaced-relation under the photovoltaic module, for positioning the photovoltaic module spaced from the tufted geosynthetic cover.

5. The apparatus as recited in claim 4, wherein the height of each spacer of the pair of spacers differs, whereby the photovoltaic module is disposed an oblique angle relative to the tufted geosynthetic cover.

6. The apparatus as recited in claim 1, further comprising at least one elongate anti-creep strip for connecting to the support of the photovoltaic module, the anti-creep strip having a plurality of projections extending from a first surface for engaging a plurality of tufts of the tufted geosynthetic cover.

7. A method of securing a photovoltaic module to a tufted geosynthetic cover, comprising the steps of:
(a) connecting an attaching harness to a support of a photovoltaic module,
(b) extending the attaching strip laterally of a side of the photovoltaic module;
(c) inserting an elongate member between a tufted geosynthetic cover and a geomembrane overlying a ground surface along a side of the photovoltaic module; and
(d) driving a fastener through the attaching harnesses and into the elongate member, for securing the photovoltaic module to the tufted geosynthetic cover.

8. The method as recited in claim 7, further comprising the steps of:
forming a slit in the tufted geosynthetic cover proximate a location for the photovoltaic module, the slit for slidably receiving the elongate member therethrough; and
sealing the slit after inserting the elongate member between the tufted geosynthetic cover and the geomembrane.

9. The method as recited in claim 7, further comprising the step of sealing the fastener secured to the attaching harness and the elongate member.

10. The method as recited in claim 7, further comprising the steps of:
providing a distal end of the elongate member with a curved face;
inserting the curved face of the elongate member into a gap between the tufted geosynthetic cover and the geomembrane; and
tapping an opposing distal end of the elongate member for being received into the gap.

11. The method as recited in claim 7, further comprising the step of positioning the photovoltaic module between a pair of elongate members received in spaced-apart relation between the tufted geosynthetic cover and the geomembrane.

12. The method as recited in claim 7, further comprising the steps of:
attaching an elongate anti-creep strip to the support, the anti-creep strip having a plurality of projections extending from a first surface; and
engaging the projections with a plurality of tufts of the tufted geosynthetic cover.

13. An apparatus for securing a photovoltaic module to a tufted geosynthetic cover overlying a ground surface, comprising:
an attaching harness for extending laterally from the support outwardly of a side of the photovoltaic module;
an elongate member for disposing between a tufted geosynthetic cover and a geomembrane overlying a ground surface; and
a plurality of fasteners each for extending through the attaching harness and into the elongate member, for securing the photovoltaic module to the tufted geosynthetic cover.

14. The apparatus as recited in claim 13, wherein the elongate member has a curved face at a distal end.

15. The apparatus as recited in claim 13, wherein the elongate member has a bull face at a distal end.

16. The apparatus as recited in claim 13, further comprising a first spacer for seating under the photovoltaic module, for positioning the photovoltaic module spaced from the tufted geosynthetic cover.

17. The apparatus as recited in claim 16, further comprising a second spacer for seating under the photovoltaic module spaced-apart from the first spacer, the second spacer having a height different from a height of the first spacer, whereby the photovoltaic module is disposed an oblique angle relative to the tufted geosynthetic cover.

18. The apparatus as recited in claim 13, further comprising an elongate anti-creep strip for connecting to the support of the photovoltaic module, the anti-creep strip having a plurality of projections extending from a first surface for engaging a plurality of tufts of the tufted geosynthetic cover.
